(19) United States
(12) Patent Application Publication
(10) Pub. No.: US 2015/0378206 A1
(43) Pub. Date: Dec. 31, 2015

(54) DISPLAY DEVICE AND MANUFACTURING METHOD THEREOF

(71) Applicant: Samsung Display Co., Ltd., Yongin-City (KR)

(72) Inventors: Woo Yong SUNG, Seoul (KR); A Ram LEE, Hwaseong-si (KR); Tae Woon CHA, Seoul (KR)

(21) Appl. No.: 14/526,290

(22) Filed: Oct. 28, 2014

(30) Foreign Application Priority Data
Jun. 26, 2014 (KR) 10-2014-0079101

(51) Int. Cl. G02F 1/1333; G02F 1/1341; G02F 1/1368; H01L 27/12; H01L 21/02

(52) U.S. Cl. CPC G02F 1/133305; H01L 27/1259; H01L 27/1248; H01L 21/0228; H01L 21/02118; H01L 21/02178; H01L 21/02186; G02F 1/1368; G02F 1/133345; G02F 1/133377; G02F 1/1341; G02F 2001/133302

(57) ABSTRACT

A display device includes: an insulation substrate including a plurality of pixel areas; a thin film transistor provided on the insulation substrate; a pixel electrode connected to the thin film transistor; a liquid crystal layer filling a microcavity; a common electrode provided on the liquid crystal layer and separated from the pixel electrode by the microcavity; a roof layer provided on the common electrode; an injection hole formed on the common electrode and the roof layer to expose part of the microcavity; an overcoat formed on the roof layer to cover the injection hole and seal the microcavity; and a passivation layer provided on the overcoat, wherein the passivation layer includes an inorganic layers.

### CROSS-REFERENCE TO RELATED APPLICATION

This application claims priority to and the benefit of Korean Patent Application No. 10-2014-0079101 filed in the Korean Intellectual Property Office on Jun. 26, 2014, the entire contents of which are incorporated herein by reference.

### BACKGROUND

(a) Field

The inventive concept relates to a display device and a manufacturing method thereof.

(b) Description of the Related Art

Display devices are required for computer monitors, televisions, mobile phones, and the like which are widely used these days. The display devices include a cathode ray tube display device, a liquid crystal display, a plasma display device, an OLED display device and the like.

The liquid crystal display, which is one of the most common types of flat panel displays currently in use, includes two sheets of display panels with field generating electrodes such as a pixel electrode, a common electrode, and the like, and a liquid crystal layer interposed therebetween. The liquid crystal display generates an electric field in the liquid crystal layer by applying a voltage to the field generating electrodes to determine alignment of liquid crystal molecules of the liquid crystal layer through the generated electric field and control polarization of incident light, thereby displaying images.

The two sheets of display panels configuring the liquid crystal display may include a thin film transistor array panel and an opposing display panel. In the thin film transistor array panel, a gate line transferring a gate signal and a data line transferring a data signal are formed to cross each other, and a thin film transistor connected with the gate line and the data line, a pixel electrode connected with the thin film transistor, and the like may be formed. In the opposing display panel, a light blocking member, a color filter, a common electrode, and the like may be formed. In some cases, the light blocking member, the color filter, and the common electrode may be formed on the thin film transistor array panel.

However, in a liquid crystal display in the related art, the two sheets of substrates are necessarily used, and respective constituent elements are formed on the two sheets of substrates, and as a result, there are problems in that the display device is heavy and thick, has a high cost, and has a long processing time.

The above information disclosed in this Background section is only for enhancement of understanding of the background of the inventive concept and therefore it may contain information that does not form the prior art.

### SUMMARY

The inventive concept has been made in an effort to provide a display device and a manufacturing method thereof having advantages of reducing weight, thickness, cost, and processing time by manufacturing the display device by using one substrate.

The inventive concept has been made in another effort to provide a display device and a manufacturing method thereof having advantages of controlling permeation of moisture through a side of a display device to prevent deterioration of performance of the display device and improve flexibility.

An exemplary embodiment of the inventive concept provides a display device including: an insulation substrate including a plurality of pixel areas; a thin film transistor provided on the insulation substrate; a pixel electrode connected to the thin film transistor; a liquid crystal layer filling a microcavity; a common electrode provided on the liquid crystal layer and separated from the pixel electrode by the microcavity; a roof layer provided on the common electrode; an injection hole formed on the common electrode and the roof layer to expose part of the microcavity; an overcoat formed on the roof layer to cover the injection hole and seal the microcavity; and a passivation layer provided on the overcoat, wherein the passivation layer includes an inorganic layer.

The passivation layer further includes an organic layer, and the passivation layer is formed by alternately stacking the organic layer.

The inorganic layer includes at least one of aluminum oxide, titanium oxide, and tin oxide.

The inorganic layer includes a first inorganic layer and a second inorganic layer which are alternately disposed.

The first inorganic layer and the second inorganic layer are about 1 Å thick.

The organic layer includes at least one of polyamide, nylon 6, nylon 66, polyethylene, polypropylene, polyurea, polythiourea, polyurethane, polyester, and polyazomethine.

The first inorganic layer includes an aluminum oxide and the second inorganic layer includes a titanium oxide.

The inorganic layer includes a plurality of inorganic layers and the organic layer includes a plurality of organic layers, and the plurality of inorganic layer and the plurality of organic layer are alternately disposed. The inorganic layer is repeatedly disposed.

Another exemplary embodiment of the inventive concept provides a method for manufacturing a display device, including: forming a thin film transistor on a substrate; forming a first insulating layer on the thin film transistor; forming a pixel electrode connected to the thin film transistor on the first insulating layer; forming a sacrificial layer on the pixel electrode; forming a common electrode on the sacrificial layer; forming a second insulating layer on the common electrode; coating an organic material on the second insulating layer and patterning the same to form a roof layer; exposing the sacrificial layer; forming a microcavity between the pixel electrode and the common electrode by removing the sacrificial layer through an exposed region; forming a liquid crystal layer by injecting a liquid crystal material into the microcavity; sealing the microcavity by forming an overcoat on the roof layer; and forming a passivation layer on the overcoat, wherein the passivation layer includes an inorganic layer.

The passivation layer further includes an organic layer, and the inorganic layer is formed by using an atomic layer deposition (ALD) method and the organic layer is formed by using a molecular layer deposition (MLD) method.

The passivation layer is formed by alternately laminating the organic layer and the inorganic layer. The alternately laminating the organic layer and the inorganic layer are performed repeatedly.

The inorganic layer includes at least one of aluminum oxide, titanium oxide, and tin oxide.

The inorganic layer is formed by alternately laminating different kinds of first inorganic layers and second inorganic layers.

The organic layer includes at least one of polyamide, nylon 6, nylon 66, polyethylene, polypropylene, polyurea, polythiourea, polyurethane, polyester, and polyazomethine.

The inorganic layer includes a first inorganic layer and a second inorganic layer which are alternately disposed, and the first inorganic layer includes an aluminum oxide and the second inorganic layer includes a titanium oxide.

The inorganic layer is about 1 Å thick.

According to the exemplary embodiment of the inventive concept, the display device and the manufacturing method thereof manufactures a display device using a substrate, thereby reducing weight, thickness, cost, and processing time.

Also, moisture permeation into the display device is prevented to improve quality of the display device.

Further, flexibility of the display device is improved such that it is applicable to a flexible display device.

### BRIEF DESCRIPTION OF THE DRAWINGS

FIG. 1 shows a top plan view of a display device according to an exemplary embodiment of the inventive concept.

FIG. 2 shows a top plan view of a pixel of a display device according to an exemplary embodiment of the inventive concept.

FIG. 3 shows a cross-sectional view of part of a display device with respect to a line III-III of FIG. 1 according to an exemplary embodiment of the inventive concept.

FIG. 4 shows a cross-sectional view of part of a display device with respect to a line IV-IV according to an exemplary embodiment of the inventive concept.

FIG. 5 shows a cross-sectional view of a passivation layer according to an exemplary embodiment of the inventive concept.

FIGS. 6, 7, 8, 9, 10, and 11 show a processing cross-sectional view of a method for manufacturing a display device according to an exemplary embodiment of the inventive concept.

FIG. 12 shows a cross-sectional image of a passivation layer according to another exemplary embodiment of the inventive concept.

FIG. 13 shows a cross-sectional image of a passivation layer according to another exemplary embodiment of the inventive concept.

FIG. 14 shows an image of the device after dipping the device into water to evaluate the passivation layer according to an exemplary embodiment of the inventive concept, and FIG. 15 shows an image of the device after dipping the device into water to evaluate the passivation layer for a comparative example.

FIG. 16 shows a graph for moisture permeability for a passivation layer according to an exemplary embodiment of the inventive concept and a comparative example.

### DETAILED DESCRIPTION OF THE EMBODIMENTS

The inventive concept will be described more fully hereinafter with reference to the accompanying drawings, in which exemplary embodiments of the inventive concept are shown. As those skilled in the art would realize, the described embodiments may be modified in various different ways, all without departing from the spirit or scope of the inventive concept.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present between the two elements. In contrast, when an element is referred to as being “directly on” another element, there are no intervening elements present.

A display device according to an exemplary embodiment of the inventive concept will now be described with reference to accompanying drawings.

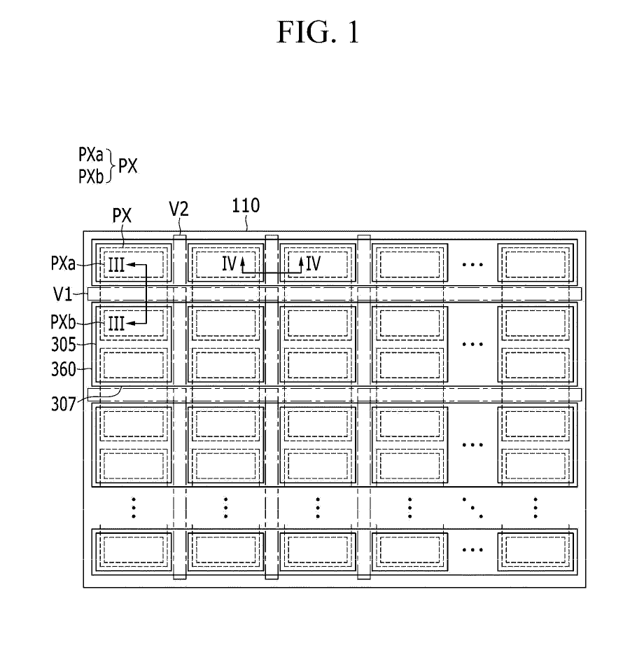

FIG. 1 shows a top plan view of a display device according to an exemplary embodiment of the inventive concept, and for convenience, FIG. 1 show some constituent elements.

The display device includes a substrate 110 made of a transparent material such as glass or plastic, and a roof layer 360 formed on the substrate 110.

The substrate 110 includes a plurality of pixel areas PXs. The pixel areas (PXs) are disposed as a matrix including a plurality of pixel rows and a plurality of pixel columns. Each pixel area PX can include a first sub-pixel area (PXa) and a second sub-pixel area (PXb). The first sub-pixel area (PXa) and the second sub-pixel area (PXb) can be disposed from top to bottom.

A first valley (V1) is provided between the first sub-pixel area (PXa) and the second sub-pixel area (PXb) and extends in the pixel row direction, and a second valley (V2) is provided between the pixel columns.

The roof layer 360 is formed on constituent elements. In this case, an injection hole 307 is formed in the first valley V1 so that constituent elements below the roof layer 360 may be exposed to the outside by removing the roof layer 360.

Each roof layer 360 has a disconnected portion in first valleys V1 such that a microcavity 305 is formed. In addition, each roof layer 360 covers respective lateral sides of the microcavity 305 in the second valley V2.

Further, the roof layer 360 is formed to be thicker than the components that are formed below the roof layer 360, and the roof layer 360 has a flat surface.

The above-described display device according to the exemplary embodiment of the inventive concept is merely an example, and numerous variations thereof are allowable. For example, the pixel area PX, the first valley V1, and the second valley V2 may have a different arrangement, a plurality of roof layers 360 may be connected to each other in the first valley V1, and each roof layer 360 can have a disconnected portion in the second valley V2 so that adjacent microcavities 305 can be connected to each other.

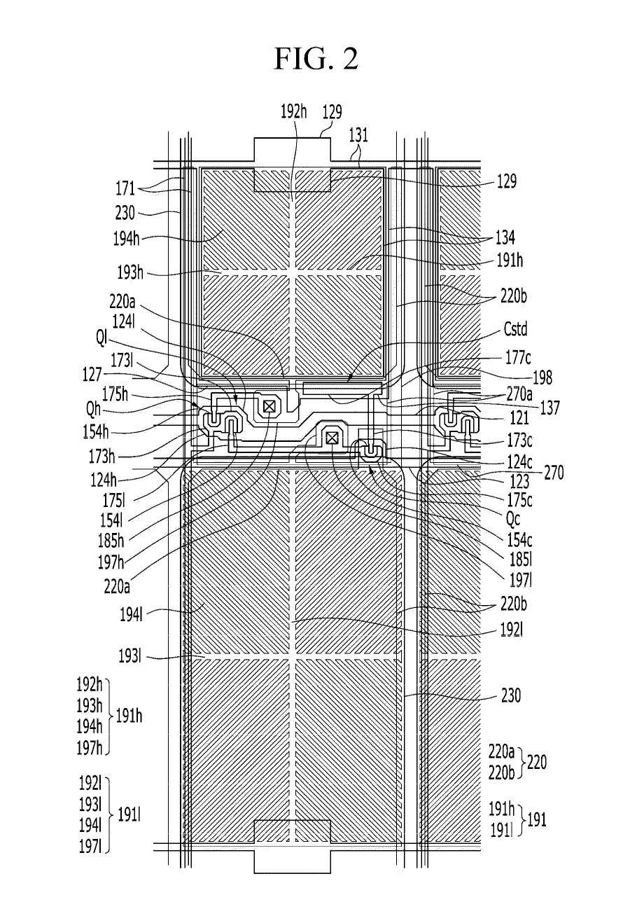

A pixel of a display device according to an exemplary embodiment of the inventive concept will now be described with reference to FIG. 2 to FIG. 5 as well as FIG. 1.

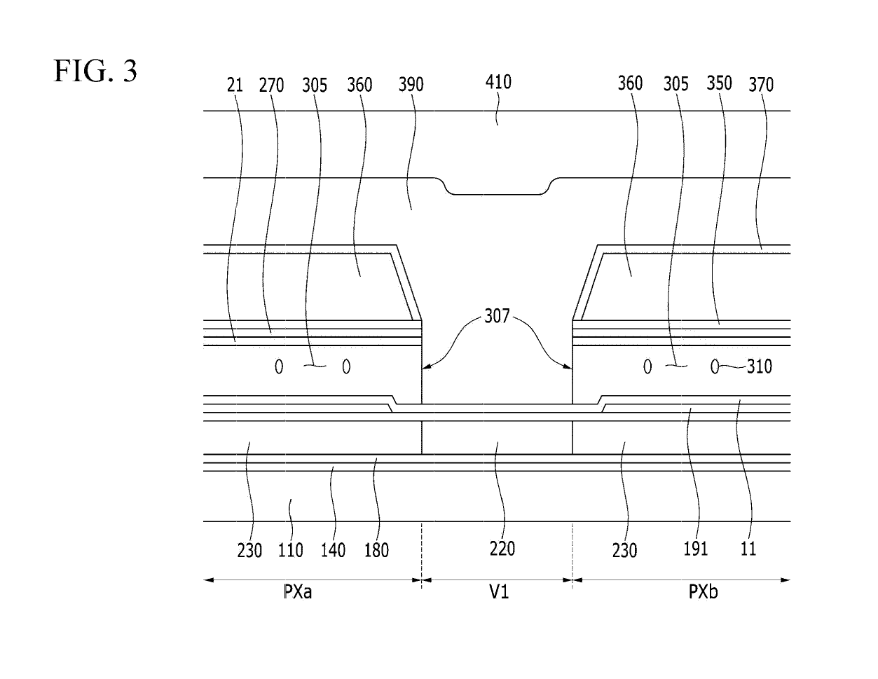

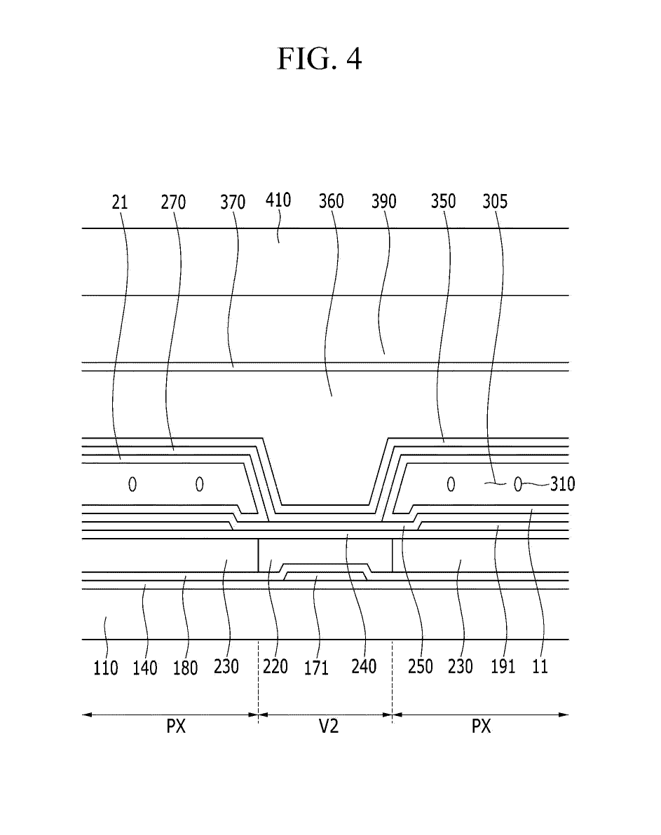

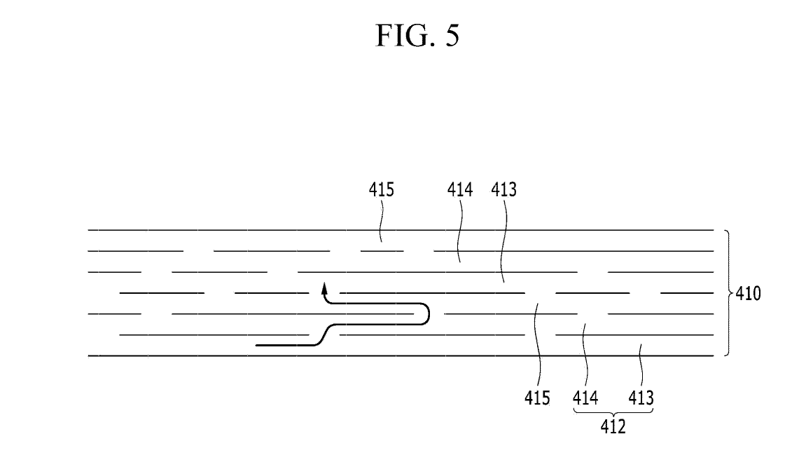

FIG. 2 shows a top plan view of a pixel of a display device according to an exemplary embodiment of the inventive concept, FIG. 3 shows a cross-sectional view of part of a display device with respect to a line III-III of FIG. 1 according to an exemplary embodiment of the inventive concept, and FIG. 4 shows a cross-sectional view of part of a display device with respect to a line IV-IV according to an exemplary embodiment of the inventive concept. FIG. 5 shows a cross-sectional view of a passivation layer according to an exemplary embodiment of the inventive concept.

Referring to FIG. 1 to FIG. 5, a plurality of gate conductors including a plurality of gate lines 121, a plurality of step-down gate lines 123, and a plurality of storage electrode lines 131 are formed on the insulation substrate 110.

The gate line 121 and the step-down gate line 123 generally extends in a horizontal direction and they transmit a gate signal. The gate conductor further includes a first gate electrode 124h and a second gate electrode 124l that are protruded upward and downward from the gate line 121, and it further includes a third gate electrode 124c that is protruded upward from the step-down gate line 123. The first gate electrode 124h and the second gate electrode 124l are connected to each other to form a protrusion. In this instance, protruded shapes of the first, second and third gate electrodes 124h, 124l, and 124c are changeable.

The storage electrode line 131 mainly extends in the horizontal direction and transmits a predetermined voltage such as the common voltage (Vcom). The storage electrode line 131 includes a storage electrode 129 protruded up and down, a pair of vertical units 134 substantially vertically extending with respect to the gate line 121, and a horizontal unit 127 connecting ends of the vertical units 134. The horizontal unit 127 includes a capacitor electrode 137 extending downward.

A gate insulating layer 140 is formed on the gate conductors 121, 123, 124h, 124l, 124c, and 131. The gate insulating layer 140 can be made of an inorganic insulating material such as a silicon nitride (SiNx), a silicon oxide (SiOx), or a silicon oxynitride (SiOxNy). Further, the gate insulating layer 140 can be formed to be a single layer or multiple layers.

A first semiconductor 154h, a second semiconductor 154l, and a third semiconductor 154c are formed on the gate insulating layer 140. The first semiconductor 154h can be provided on the first gate electrode 124h, the second semiconductor 154l can be provided on the second gate electrode 124l, and the third semiconductor 154c can be provided on the third gate electrode 124c. The first semiconductor 154h can be connected to the second semiconductor 154l, and the second semiconductor 154l can be connected to the third semiconductor 154c. Also, the first semiconductor 154h can extend to a bottom part of a data line 171. The first to third semiconductors 154h, 154l, and 154c can be made of amorphous silicon, polycrystalline silicon, or a metal oxide.

An ohmic contact (not shown) can be respectively formed on the first to third semiconductors 154h, 154l, and 154c. The ohmic contact can be made of a material such as n+hydrogenated amorphous silicon doped with a metal or an n-type impurity at a high concentration.

A data conductor including the data line 171, a first source electrode 173h, a second source electrode 173l, a third source electrode 173c, a first drain electrode 175h, a second drain electrode 175l, and a third drain electrode 175c is formed on the first to third semiconductors 154h, 154l, and 154c.

The data line 171 transmits a data signal and generally extends in the vertical direction to cross the gate line 121 and the step-down gate line 123. The data line 171 includes the first source electrode 173h and the second source electrode 173l extending toward the first gate electrode 124h and the second gate electrode 124l and connected to each other.

The first drain electrode 175h, the second drain electrode 175l, and the third drain electrode 175c include a wide first end portion and a bar-type second end portion. The bar-type end portions of the first drain electrode 175h and the second drain electrode 175l are partially surrounded by the first source electrode 173h and the second source electrode 173l. The wide first end portion of the second drain electrode 175l extends to form the U-shaped third source electrode 173c. A wide end portion 177c of the third drain electrode 175c overlaps the capacitor electrode 137 to form a step-down capacitor (Cstd), and the bar-type end portion is partially surrounded by the third source electrode 173c.

The first gate electrode 124h, the first source electrode 173h, and the first drain electrode 175h form a first thin film transistor (Qh) together with the first semiconductor 154h, the second gate electrode 124l, the second source electrode 173l, and the second drain electrode 175l form a second thin film transistor (Ql) together with the second semiconductor 154l, and the third gate electrode 124c, the third source electrode 173c, and the third drain electrode 175c form a third thin film transistor (Qc) together with the third semiconductor 154c.

The first semiconductor 154h, the second semiconductor 154l, and the third semiconductor 154c can be connected to each other and can have substantially the same shape as the data conductors 171, 173h, 173l, 173c, 175h, 175l, and 175c and the ohmic contact below them except at a channel region between the source electrodes 173h, 173l, and 173c and the drain electrodes 175h, 175l, and 175c in a plan view.

In the first semiconductor 154h, there is a portion that it is not covered by the first source electrode 173h and the first drain electrode 175h but is exposed between the first source electrode 173h and the first drain electrode 175h, in the second semiconductor 154l, there is a portion that it is not covered by the second source electrode 173l and the second drain electrode 175l but is exposed between the second source electrode 173l and the second drain electrode 175l, and in the third semiconductor 154c, there is a portion that it is not covered by the third source electrode 173c and the third drain electrode 175c but is exposed between the third source electrode 173c and the third drain electrode 175c.

A first insulating layer 180 is formed on the data conductors 171, 173h, 173l, 173c, 175h, 175l, and 175c and the semiconductors 154h, 154l, and 154c exposed between the source electrodes 173h, 173l, and 173c and the drain electrodes 175h, 175l, and 175c. The first insulating layer 180 can be formed with an organic insulating material or an inorganic insulating material, and can be formed to be a single layer or multiple layers.

A color filter 230 is formed in the pixel area (PX) on the first insulating layer 180. Each color filter 230 can display one of primary colors such as red, green, and blue. The color filter 230 is not limited to the three primary colors of red, green, and blue and it may be other primary colors such as cyan, magenta, yellow, and white-based colors. Differing from the illustration, the color filter 230 can extend in the column direction along the neighboring data lines 171.

A light blocking member 220 is formed in a region between the neighboring color filters 230. The light blocking member 220 is formed on a boundary of the pixel area (PX) and the thin film transistor to prevent leakage of light. The color filter 230 is formed in the first sub-pixel area (PXa) and the second sub-pixel area (PXb), and the light blocking member 220 can be formed between the first sub-pixel area (PXa) and the second sub-pixel area (PXb).

The light blocking member 220 extends along a direction in which the gate line 121 and the step-down gate line 123 extend, and it includes a horizontal light blocking member 220a for covering a region in which the first thin film transistor (Qh), the second thin film transistor (Ql), and the third thin film transistor (Qc) are provided, and a vertical light blocking member 220b extended along the data line 171. That is, the horizontal light blocking member 220a can be formed in the first valley (V1), and the vertical light blocking member 220b can be formed in the second valley (V2). The color filter 230 can overlap the light blocking member 220 in a predetermined region.

A second insulating layer 240 can be further formed on the color filter 230 and the light blocking member 220. The second insulating layer 240 can be formed with an inorganic insulating material such as a silicon nitride (SiNx), a silicon oxide (SiOx), or a silicon oxynitride (SiOxNy). The second insulating layer 240 protects the color filter 230 made of an organic material and the light blocking member 220, and it can be omitted as needed.

A plurality of first contact holes 185h and a plurality of second contact holes 185l for exposing a wide end portion of the first drain electrode 175h and a wide end portion of the second drain electrode 175l are formed on the second insulating layer 240, the light blocking member 220, and the first insulating layer 180.

A pixel electrode 191 is formed on the second insulating layer 240. The pixel electrode 191 can be formed of a transparent metal material such as indium tin oxide (ITO) or indium zinc oxide (IZO).

The pixel electrode 191 includes a first sub-pixel electrode 191h and a second sub-pixel electrode 191l that are separated from each other with the gate line 121 and the step-down gate line 123 formed therebetween, that are disposed at a top and a bottom of the pixel area PX with respect to the gate line 121 and the step-down gate line 123, and that neighbor each other in the column direction. That is, the first sub-pixel electrode 191h is separated from the second sub-pixel electrode 191l with the first valley (V1) formed therebetween, the first sub-pixel electrode 191h is provided in the first sub-pixel area (PXa), and the second sub-pixel electrode 191l is provided in the second sub-pixel area (PXb).

The first sub-pixel electrode 191h and the second sub-pixel electrode 191l are connected to the first drain electrode 175h and the second drain electrode 175l through the first contact hole 185h and the second contact hole 185l. Therefore, when the first thin film transistor (Qh) and the second thin film transistor (Ql) are turned on, they receive a data voltage from the first drain electrode 175h and the second drain electrode 175l.

The first sub-pixel electrode 191h and the second sub-pixel electrode 191l are quadrangular, and the first sub-pixel electrode 191h and the second sub-pixel electrode 191l include a cross stem having horizontal stems 193h and 193l and vertical stems 192h and 192l crossing the horizontal stems 193h and 193l. Further, the first sub-pixel electrode 191h and the second sub-pixel electrode 191l include a plurality of minute branches 194h and 194l and protrusions 197h and 197l that are protruded upward or downward from edges of the sub-pixel electrodes 191h and 191l.

The pixel electrode 191 is divided into four sub-regions by the horizontal stems 193h and 193l and the vertical stems 192h and 192l. The minute branches 194h and 194l extend obliquely from the horizontal stems 193h and 193l and the vertical stems 192h and 192l, and the extension direction forms an angle of substantially 45 or 135 degrees with respect to the gate line 121 or the horizontal stems 193h and 193l. Also, directions in which the minute branches 194h and 194l of two neighboring sub-regions extend may be orthogonal.

The first sub-pixel electrode 191h further includes an outer stem connecting an outer part of the sub-pixel electrode, while the second sub-pixel electrode 191l further includes a horizontal unit provided to an upper end and a lower end, and a left/right vertical unit 198 provided to the left and right of the first sub-pixel electrode 191h. The left/right vertical unit 198 can prevent capacitive coupling between the data line 171 and the first sub-pixel electrode 191h.

The arrangement of the pixel area, the structure of the thin film transistor, and the shape of the pixel electrode described above are just exemplified, and the inventive concept is not limited thereto and may be variously modified.

A common electrode 270 is formed on the pixel electrode 191 so as to be spaced apart from the pixel electrode 191 at a regular distance. The microcavity 305 is formed between the pixel electrode 191 and the common electrode 270. That is, the microcavity 305 is surrounded by the pixel electrode 191 and the common electrode 270. A width and an area of the microcavity 305 may be variously modified according to size and resolution of the display device.

The common electrode 270 may be made of a transparent metal material such as indium tin oxide (ITO) and indium zinc oxide (IZO). A predetermined voltage may be applied to the common electrode 270, and an electric field may be generated between the pixel electrode 191 and the common electrode 270.

A first alignment layer 11 is formed on the pixel electrode 191. The first alignment layer 11 may also be formed on the second insulating layer 240 which is not covered by the pixel electrode 191.

A second alignment layer 21 is formed below the common electrode 270 to face the first alignment layer 11.

The first alignment layer 11 and the second alignment layer 21 may be formed of vertical alignment layers and made of alignment materials such as polyamic acid, polysiloxane, and polyimide. The first and second alignment layers 11 and 21 may be connected to each other at the edge of the pixel area (PX).

A liquid crystal layer including liquid crystal molecules 310 is formed in the microcavity 305 positioned between the pixel electrode 191 and the common electrode 270. The liquid crystal molecules 310 have negative dielectric anisotropy, and may be arranged perpendicular to the insulation substrate 110 while the electric field is not applied. .

The first sub-pixel electrode 191h and the second sub-pixel electrode 191l to which the data voltages are applied generate an electric field together with the common electrode 270 to determine directions of arrangement of the liquid crystal molecules 310 positioned in the microcavity 305 between the two electrodes 191 and 270. As such, luminance of light passing through the liquid crystal layer varies according to the determined directions of the liquid crystal molecules 310.

A third insulating layer 350 may be further formed on the common electrode 270. The third insulating layer 350 can be made of inorganic insulating materials such as a silicon nitride (SiNx), a silicon oxide (SiOx), or a silicon oxynitride (SiOxNy), and may be omitted if necessary.

The roof layer 360 is formed on the third insulating layer 350. The roof layer 360 may be made of an organic material. The microcavity 305 is formed below the roof layer 360, and the roof layer 360 is hardened by a hardening process to thus maintain the shape of the microcavity 305. That is, the roof layer 360 is formed to be separated from the pixel electrode 191 with the microcavity 305 therebetween.

The roof layer 360 is formed in each pixel area PX and the second valley V2 along a pixel row, and is not formed in the first valley V1. That is, the roof layer 360 is not formed between the first sub-pixel area PXa and the second sub-pixel area PXb. The microcavity 305 is formed below the roof layer 360 at the first sub-pixel area PXa and the second sub-pixel area PXb. In the second valley V2, the microcavity 305 is not formed below the roof layer 360. Accordingly, a thickness of the roof layer 360 at the second valley V2 may be thicker than a thickness of the roof layer 360 at the first sub-pixel area PXa and the second sub-pixel area PXb. The upper surface and respective sides of the microcavity 305 are formed to be covered by the roof layer 360.

The injection hole 307 for exposing part of the microcavity 305 is formed on the common electrode 270, the third insulating layer 350, and the roof layer 360. Injection holes 307 may be formed to face each other at the edges of the first sub-pixel area PXa and the second sub-pixel area PXb. That is, each injection hole 307 may be formed to expose the sides of the microcavity 305 corresponding to a lower side of the first sub-pixel area PXa and an upper side surface of the second sub-pixel area PXb. Since the microcavity 305 is exposed by the injection hole 307, an aligning agent, a liquid crystal material, or the like may be injected into the microcavity 305 through the injection hole 307.

A fourth insulating layer 370 and an overcoat 390 can be provided on the roof layer 360. The overcoat 390 is formed to cover the injection hole 307 where the part of the microcavity 305 is exposed outside. That is, the overcoat 390 may seal the microcavity 305 so that the liquid crystal molecules 310 formed in the microcavity 305 are not discharged outside. Since the overcoat 390 contacts the liquid crystal molecules 310, the overcoat 390 may be made of a material which does not react with the liquid crystal molecules 310. For example, the overcoat 390 may be made of parylene and the like.

The overcoat 390 may be formed as a multilayer such as a double layer and a triple layer. The double layer is composed of two layers made of different materials. The triple layer is composed of three layers, and materials of adjacent layers are different from each other. For example, the overcoat 390 may include a layer made of an organic insulating material or a layer made of an inorganic insulating material.

A passivation layer 410 is provided on the overcoat 390. The passivation layer 410 may include at least one inorganic layer 412. FIG. 5 shows an exemplary embodiment including a plurality of inorganic layers 412, and without being restricted to this, it may include a single inorganic layer.

Referring to FIG. 5, the passivation layer 410 may include an inorganic layer 412 and an organic layer 415 that are laminated alternatingly. A plurality of the inorganic layer 412 and the organic layer 415 inorganic layer 412 may be formed repeatedly to form the passivation layer 410.

Also, the inorganic layer 412 may include a plurality of layers having different materials, and for example, a first inorganic layer 413 of a predetermined material is provided, and a second inorganic layer 414 of another material may be alternately stacked thereon.

In this instance, the first inorganic layer 413 and the second inorganic layer 414 can be about 1 Å thick.

The inorganic layer 412 may include at least one of aluminum oxide (Al₂O₃), titanium oxide (TiO₂), and tin oxide (SnO₂). For example, regarding the inorganic layer 412 including a plurality of layers with different materials, the first inorganic layer 413 can be made of aluminum oxide and the second inorganic layer 414 can be made of titanium oxide. In addition, the first inorganic layer 413 can be made of aluminum oxide and the second inorganic layer 414 can be made of tin oxide. The material of the inorganic layer 412 is not restricted to the above-described example, and any kinds of materials that can be deposited at a low temperature are usable.

When one of the inorganic layers 413 and 414 is formed with a thickness of substantially 1 Å, pin holes in which the inorganic layers 413 and 414 are not uniformly formed may be generated. When another inorganic layer is stacked on the inorganic layers including the pin hole, the pin holes in the inorganic layers may be covered by the another inorganic layers formed above an underlying inorganic layer. Thus, the inorganic layer 412 which does not have a pin hole can be formed. The passivation layer 410 may further include an organic layer 415. As shown in FIG. 5, the organic layer 415 can be provided between a plurality of inorganic layers 412, and without being restricted to this, it can be provided on an outermost part of the inorganic layers 412.

A material of the organic layer 415 may include at least one of polyamide, nylon 6, nylon 66, polyethylene, polypropylene, polyurea, polythiourea, polyurethane, polyester, and polyazomethine, and it is not restricted thereto.

The pin holes in the inorganic layer 412 may be covered by the organic layer. Therefore, the combination of the inorganic layer 412 and the organic layer 415 may prevent a permeation of water vapor from the atmosphere to the liquid crystal.

Different kinds of the inorganic layer and the organic layer can be laminated with various combinations. The different kinds of the inorganic layers can be alternatingly laminated on the fourth insulating layer and the organic layer can be provided on the outermost part of the stacked inorganic layers. The different kinds of the inorganic layers and organic layers can be laminated alternatingly and the combination of the inorganic layer and the organic layer can be formed repeatedly on the fourth insulating layer.

According to the above exemplary embodiment, the respective inorganic layers and organic layers are formed to be very thin, and layers stacked on the underlying layers are formed to fill the pin holes formed in the underlying layers, so the boundary between the stacked layers can be unclear.

According to the passivation layer 410, the inorganic layer may prevent the moisture from permeating into the display device, thus reliability of the display device may be increased. Further, laminated structure of the inorganic layer and the organic layer in the passivation layer 410 may have flexibility, and the passivation layer may be applicable to the flexible display.

Although not shown, a polarizer may be further formed on a top side and a bottom side of the display device. The polarizer includes a first polarizer and a second polarizer. The first polarizer can be attached to the bottom side of the insulation substrate 110, and the second polarizer can be attached to the passivation layer 410.

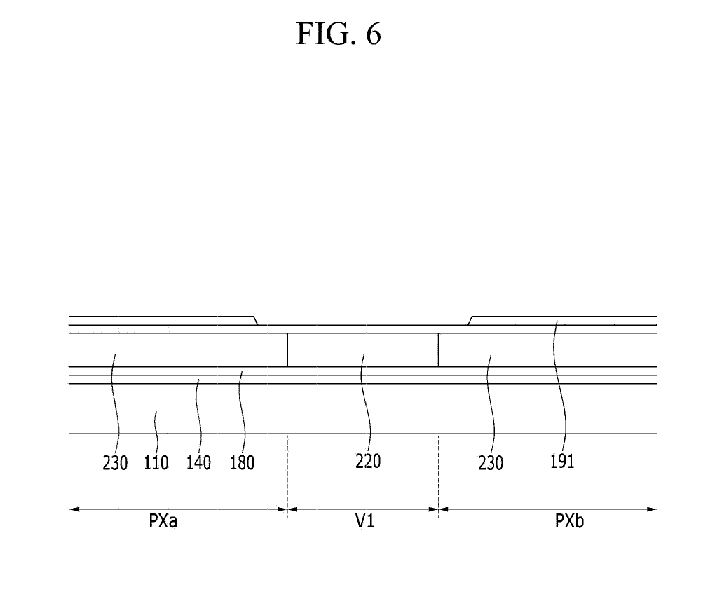

A method for manufacturing a display device according to an exemplary embodiment of the inventive concept will now be described with reference to FIG. 6 to FIG. 11 together with FIG. 1 to FIG. 5.

FIG. 6 to FIG. 11 show cross-sectional views of a method for manufacturing a display device according to an exemplary embodiment of the inventive concept.

As shown in FIG. 2 and FIG. 6, a gate line 121 and a step-down gate line 123 extending in one direction are formed on an insulation substrate 110 made of glass or plastic. A first gate electrode 124h, a second gate electrode 124l, and a third gate electrode 124c which protrude from the gate line 121 may be formed at the same time when the gate line 121 and the step-down gate line 123 are formed.

Further, a storage electrode line 131 may be formed together with the gate line 121 and the step-down gate line 123 so as to be spaced apart from the gate line 121, the step-down gate line 123, and the first to third gate electrodes 124h, 124l, and 124c.

A gate insulating layer 140 is formed on the substrate 110 including the gate line 121, the step-down gate line 123, the first to third gate electrodes 124h, 124l, and 124c, and the storage electrode line 131 by using an inorganic insulating material such as a silicon oxide (SiOx) or a silicon nitride (SiNx). The gate insulating layer 140 may be formed as a single layer or multiple layers.

A first semiconductor 154h, a second semiconductor 154l, and a third semiconductor 154c are formed by depositing and then patterning a semiconductor material such as amorphous silicon, polycrystalline silicon, and a metal oxide on the gate insulating layer 140. The first semiconductor 154h may be positioned on the first gate electrode 124h, the second semiconductor 154l may be positioned on the second gate electrode 124l, and the third semiconductor 154c may be positioned on the third gate electrode 124c.

A data line 171 extending in the other direction is formed by depositing and then patterning a conductive material such as a metal. The metal material may be formed as a single layer or multiple layers.

A first source electrode 173h protruding above the first gate electrode 124h from the data line 171, and a first drain electrode 175h spaced apart from the first source electrode 173h are formed together. A second source electrode 173l connected with the first source electrode 173h and a second drain electrode 175l spaced apart from the second source electrode 173l, are formed together with the first source electrode 173h and a first drain electrode 175h. A third source electrode 173c extending from the second drain electrode 175l, and a third drain electrode 175c spaced apart from the third source electrode 173c are formed together with the first source electrode 173h and a first drain electrode 175h.

The first to third semiconductors 154h, 154l, and 154c, the data line 171, the first to third source electrodes 173h, 173l, and 173c, and the first to third drain electrodes 175h, 175l, and 175c may be formed by sequentially depositing and then simultaneously patterning a semiconductor material and a metal material. In this case, the first semiconductor 154h may extend to the lower portion of the data line 171.

The first/second/third gate electrodes 124h/124l/124c, the first/second/third source electrodes 173h/173l/173c, and the first/second/third drain electrodes 175h/175l/175c form first/second/third thin film transistors (TFTs) Qh/Ql/Qc together with the first/second/third semiconductors 154h/154l/154c, respectively.

A first insulating layer 180 is formed on the data line 171, the first to third source electrodes 173h, 173l, and 173c, the first to third drain electrodes 175h, 175l, and 175c, and the semiconductors 154h, 154l, and 154c exposed between the respective source electrodes 173h/173l/173c and the respective drain electrodes 175h/175l/175c. The first insulating layer 180 may be made of an organic insulating material or an inorganic insulating material, and may be formed as a single layer or multiple layers.

A color filter 230 is formed in each pixel area PX on the first insulating layer 180. The color filter 230 is formed in the first sub-pixel area PXa and the second sub-pixel area PXb, and may not be formed at the first valley V1. Further, color filters 230 having the same color may be formed in a column direction of the plurality of pixel areas PXs. In the case of forming the color filter 230 having three colors, a first colored color filter 230 may be first formed and then a second colored color filter 230 may be formed by shifting a mask. The second colored color filter 230 may be formed and then a third colored color filter may be formed by shifting a mask.

A light blocking member 220 is formed on a boundary of each pixel area PX on the first insulating layer 180 and the thin film transistor

The light blocking member 220 may be formed at the first valley V1 positioned between the first sub-pixel area PXa and the second sub-pixel area PXb.

Hereinabove, it is described that the light blocking member 220 is formed after forming the color filters 230, but the inventive concept is not limited thereto, and the light blocking member 220 may be first formed and then the color filters 230 may be formed.

A second insulating layer 240 made of an inorganic insulating material such as a silicon nitride (SiNx), a silicon oxide (SiOx), and a silicon oxynitride (SiOxNy) is formed on the color filter 230 and the light blocking member 220.

A first contact hole 185h is formed by etching the first insulating layer 180, the light blocking member 220, and the second insulating layer 240 so as to expose a part of the first drain electrode 175h, and a second contact hole 185l is formed so as to expose a part of the second drain electrode 175l.

A first sub-pixel electrode 191h is formed in the first sub-pixel area PXa and a second sub-pixel electrode 191l is formed in the second sub-pixel area PXb, by depositing and then patterning a transparent conductive material such as indium tin oxide (ITO) and indium zinc oxide (IZO) on the second insulating layer 240. The first sub-pixel electrode 191h and the second sub-pixel electrode 191l may be separated from each other with the first valley V1 formed therebetween. The first sub-pixel electrode 191h is connected with the first drain electrode 175h through the first contact hole 185h, and the second sub-pixel electrode 191l is connected to the second drain electrode 175l through the second contact hole 185l.

Horizontal stems 193h and 193l and vertical stems 192h and 192l crossing the horizontal stems 193h and 193l are formed in the first sub-pixel electrode 191h and the second sub-pixel electrode 191l, respectively. Further, a plurality of minute branches 194h and 194l, which obliquely extend from the horizontal stems 193h and 193l and the vertical stems 192h and 192l, are formed.

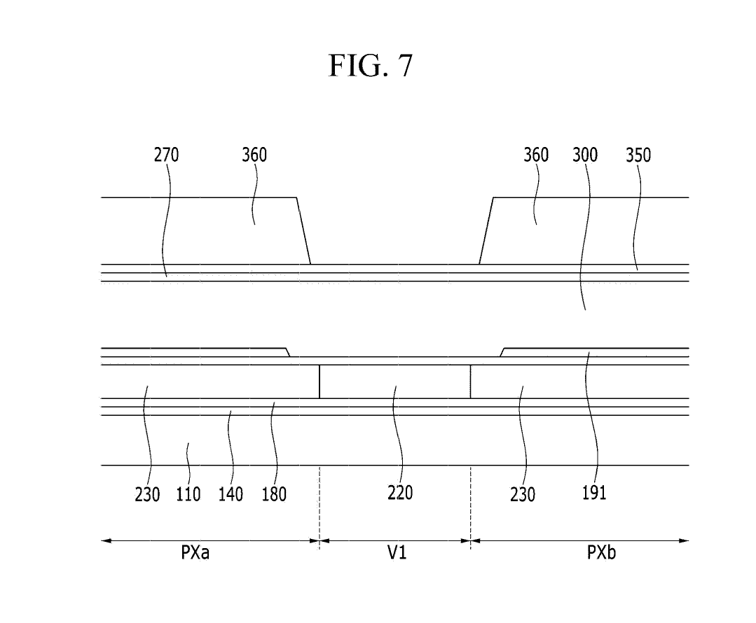

As shown in FIG. 7, a sacrificial layer 300 is formed by coating a photosensitive organic material on the pixel electrode 191 and performing a photolithography process.

Sacrificial layers 300 are formed to be connected along a plurality of pixel columns. That is, the sacrificial layer 300 is formed to cover each pixel area PX, and is formed to cover the first valley V1 positioned between the first sub-pixel area PXa and the second sub-pixel area PXb.

A common electrode 270 is formed by depositing a transparent metal material such as indium tin oxide (ITO) and indium zinc oxide (IZO) on the sacrificial layer 300.

A third insulating layer 350 may be formed on the common electrode 270. The third insulating layer 350 may be formed of an inorganic insulating material such as a silicon nitride (SiNx), a silicon oxide (SiOx), and a silicon oxynitride (SiOxNy).

A roof layer 360 is formed by coating and patterning an organic material on the third insulating layer 350. In this case, the organic material positioned at the first valley V1 may be patterned so as to be removed. As a result, roof layers 360 may be formed to be connected to each other along a plurality of pixel rows.

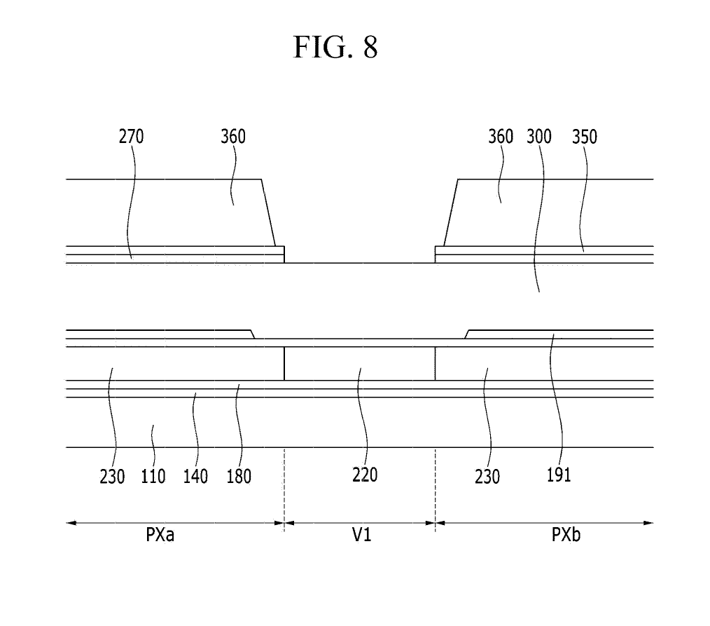

As shown in FIG. 8, the third insulating layer 350 and the common electrode 270 are patterned by using the roof layer 360 as a mask. The third insulating layer 350 may be dry-etched by using the roof layer 360 as a mask and then the common electrode 270 may be wet-etched.

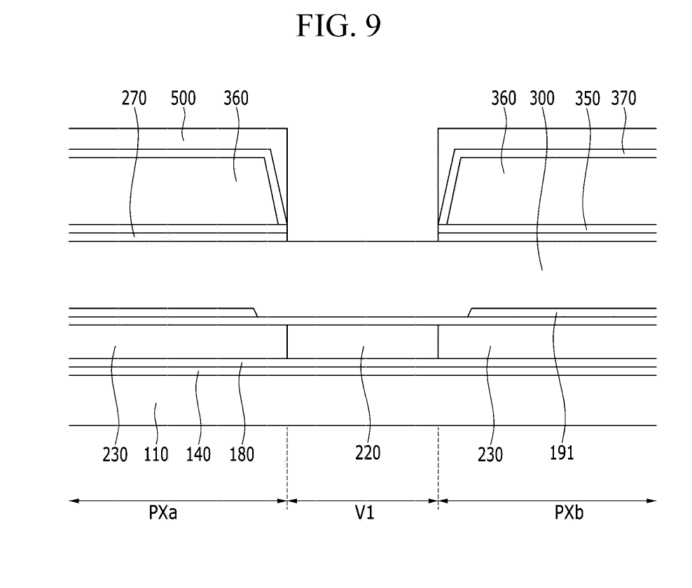

As shown in FIG. 9, a fourth insulating layer 370 made of an inorganic insulating material such as a silicon nitride (SiNx), a silicon oxide (SiOx), and a silicon oxynitride (SiOxNy) may be formed on the roof layer 360.

A photoresist 500 is coated on the fourth insulating layer 370, and the photoresist 500 is patterned by a photolithography process. In this instance, the photoresist 500 positioned at the first valley V1 may be removed. The fourth insulating layer 370 is etched by using the patterned photoresist 500 as a mask. That is, the fourth insulating layer 370 provided in the first valley V1 is removed.

The third insulating layer 350 and the common electrode 270 which are not covered by the photoresist 500 are removed using the photoresist 500 and the roof layer 360 as a mask to expose the sacrificial layer 300 so no alignment error is generated.

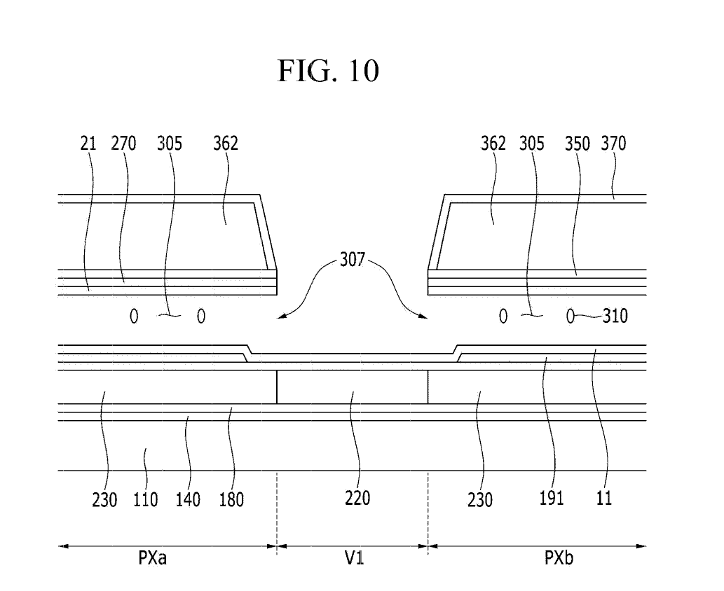

As shown in FIG. 10, a development solution or stripper solution is supplied onto the substrate 110 in which the sacrificial layer 300 is exposed to entirely remove the sacrificial layer 300. An ashing process may be used to entirely remove the sacrificial layer 300. Of course, a combination of a developing or a stripping process and the ashing process may be used to remove the sacrificial layer 300.

When the sacrificial layer 300 is removed, a microcavity 305 is provided at a position where the sacrificial layer 300 was disposed.

The pixel electrode 191 is separated from the common electrode 270 with the microcavity 305 therebetween, and the pixel electrode 191 is separated from the roof layer 360 with the microcavity 305 therebetween. The common electrode 270 and the roof layer 360 are formed to cover an upper surface and respective side surfaces of the microcavity 305.

The microcavity 305 is exposed to the outside through a portion from which the roof layer 360, the third insulating layer 350, and the common electrode 270 are removed, which is called an injection hole 307. The injection hole 307 is formed along the first valley V1. For example, the injection hole 307 may be formed to expose opposite edges of the first sub-pixel area PXa and the second sub-pixel area PXb. That is, the injection hole 307 may be formed to correspond to a lower edge of the first sub-pixel area PXa and an upper edge of the second sub-pixel area PXb to expose the side of the microcavity 305. Differently from this, the injection hole 307 may be formed along a second valley V2.

The substrate 110 is heated to harden the roof layer 360 so that the shape of the microcavity 305 may be maintained by the roof layer 360.

When an aligning agent which contains an aligning material is deposited onto the substrate 110 by a spin coating method or an inkjet method, the aligning agent is injected into the microcavity 305 through the injection hole 307. When the hardening process is performed after injecting the aligning agent into the microcavity 305, a solvent in the aligning agent is evaporated and the aligning material remains on an inner wall of the microcavity 305.

Accordingly, a first alignment layer 11 may be formed on the pixel electrode 191 and a second alignment layer 21 may be formed below the common electrode 270. The first alignment layer 11 and the second alignment layer 21 are formed to be opposite to each other with the microcavity 305 therebetween, and are formed to be connected to each other at the edge of the pixel area PX.

In this case, the first and second alignment layers 11 and 21 may be aligned in a direction perpendicular to the substrate 110 except at the side of the microcavity 305. Additionally, a process which irradiates UV onto the first and second alignment layers 11 and 21 is performed so as to align the first and second alignment layers 11 and 21 in a direction parallel to the substrate 110.

Next, when a liquid crystal material which is formed of liquid crystal molecules 310 is provided onto the substrate 110 by an inkjet method or a dispensing method, the liquid crystal material is injected into the microcavity 305 through the injection hole 307. In this instance, the liquid crystal material may be provided in the injection holes 307 formed along odd-numbered first valleys V1 but may not be deposited in the injection holes 307 formed along even-numbered first valleys V1. On the contrary, the liquid crystal material may be deposited in the injection holes 307 formed along even-numbered first valleys V1 but may not be deposited in injection holes 307 formed along odd-numbered first valleys V1.

When the liquid crystal material is provided in the injection holes 307 formed along the odd-numbered first valleys V1, the liquid crystal material enters the microcavity 305 through the injection hole 307 by capillary force. Air in the microcavity 305 is discharged through the injection hole 307 formed along the even-numbered first valleys V1 so that the liquid crystal material fills the microcavity 305.

Alternatively, the liquid crystal material may be provided in all the injection holes 307. That is, the liquid crystal material may be provided in the injection holes 307 formed along the odd-numbered first valleys V1 and the injection holes 307 formed along the even-numbered first valleys V1.

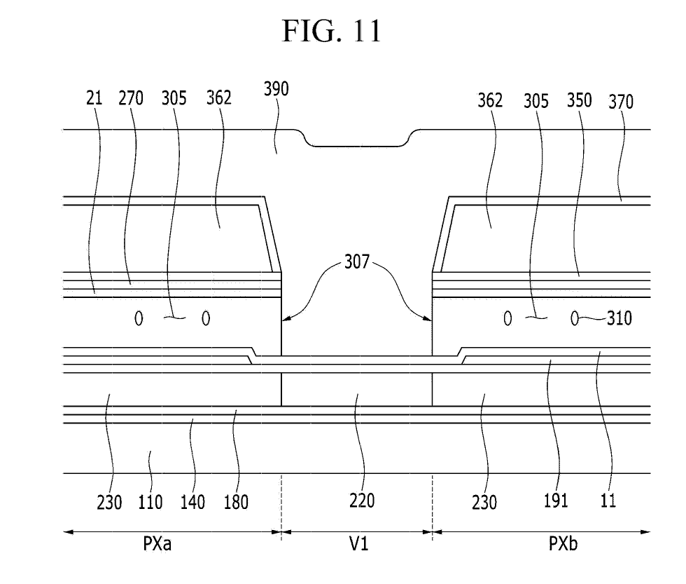

As shown in FIG. 11, a material which does not react with the liquid crystal molecules 310 is formed on the fourth insulating layer 370 to form an overcoat 390. The overcoat 390 is formed so as to cover the injection hole 307 through which the microcavity 305 is exposed to the outside to seal the microcavity 305.

A passivation layer 410 is formed on the overcoat 390 to form a display device shown in FIG. 3 to FIG. 5.

The passivation layer 410 is formed to include at least one inorganic layer 412. FIG. 5 shows a display device including a plurality of inorganic layers 412 according to an exemplary embodiment of the inventive concept, and without being restricted to this, the display device may include an inorganic layer.

The passivation layer 410 may include an inorganic layer 412 and an organic layer 415 that are laminated alternatingly. A plurality of the inorganic layer 412 and the organic layer 415 inorganic layer 412 may be formed repeatedly to form the passivation layer 410.

The inorganic layer 412 may include a plurality of layers having different materials, and for example, the first inorganic layer 413 of a predetermined material can be provided and the second inorganic layer 414 of another material can be alternately stacked thereon.

In this instance, the first inorganic layer 413 and the second inorganic layer 414 can be substantially 1 Å thick, respectively.

The inorganic layer 412 can include at least one of aluminum oxide (Al₂O₃), titanium oxide (TiO₂), and tin oxide (SnO₂). For example, regarding the inorganic layer 412 including a plurality of layers with materials, the first inorganic layer 413 can be made of aluminum oxide and the second inorganic layer 414 can be made of titanium oxide. In addition, the first inorganic layer 413 can be made of aluminum oxide and the second inorganic layer 414 can be made of tin oxide. The material of the inorganic layer 412 is not restricted to the above-described example, and any kinds of materials that can be deposited at a low temperature are usable.

When one of the inorganic layers 413 and 414 is formed with a thickness of substantially 1 Å, pin holes in which the inorganic layers 413 and 414 are not uniformly formed may be generated. When another inorganic layer is stacked on the inorganic layers including the pin hole, the pin holes in the inorganic layers may be covered by the another inorganic layers formed above an underlying inorganic layer. Thus, the inorganic layer 412 which does not have a pin hole can be formed.

The passivation layer 410 may further include an organic layer 415. As shown in FIG. 5, the organic layer 415 can be provided between a plurality of inorganic layers 412, and without being restricted to this, it can be provided on an outermost part of the inorganic layers 412.

The material of the organic layer 415 may include at least one of polyamide, nylon 6, nylon 66, polyethylene, polypropylene, polyurea, polythiourea, polyurethane, polyester, and polyazomethine, and it is not restricted thereto.

The inorganic layer 412 can be formed by using an atomic layer deposition (ALD) method, and the organic layer 415 can be formed by using a molecular layer deposition (MLD) method.

Sources for forming the inorganic layer and the organic layer can be mounted on an apparatus for forming the passivation layer 410, and for example, a first source for depositing aluminum oxide, a second source for depositing titanium oxide, and a third source for depositing an organic layer can be mounted on an apparatus for forming the passivation layer 410 to perform a deposition process. According to the example, when a scanning device is used to form the passivation layer 410, the scanning device forms a first lamination structure including a first inorganic layer of aluminum oxide, a second inorganic layer of titanium oxide and an organic layer. The scanning device may repeat the process to form a second lamination structure including the first inorganic layer of aluminum oxide, the second inorganic layer of titanium oxide and the organic layer on the first lamination structure organic layer. According to the manufacturing method, the manufacturing time can be reduced.

However, as described above, the inorganic layer 412 formed by the atomic layer deposition method may have pin holes in it, and the organic layer 415 that is stacked on the inorganic layer through the molecular layer deposition method may fill the pin holes, so the boundary between the stacked layers can be unclear. Therefore, the combination of the inorganic layer 412 and the organic layer 415 may not have pin holes.

Different kinds of the inorganic layer and the organic layer can be laminated with various combinations. The different kinds of the inorganic layers can be alternatingly laminated on the fourth insulating layer and the organic layer can be provided on the outermost part of the stacked inorganic layers. The different kinds of the inorganic layers and organic layers can be laminated alternatingly and the combination of the inorganic layer and the organic layer can be formed repeatedly on the fourth insulating layer.

According to the above exemplary embodiment, the respective inorganic layers and organic layers are formed to be very thin, and layers stacked on the underlying layers are formed to fill the pin holes formed in the underlying layers, so the boundary between the stacked layers can be unclear.

According to the passivation layer 410, the inorganic layer may prevent the moisture from permeating into the display device, thus reliability of the display device may be increased. Further, laminated structure of the inorganic layer and the organic layer in the passivation layer 410 may have flexibility, and the passivation layer may be applicable to the flexible display.

Although not shown, a polarizer may be further attached to the top side and the bottom side of the display device. The polarizer includes a first polarizer and a second polarizer. The first polarizer can be attached to the bottom side of the substrate 110, and the second polarizer can be attached to the passivation layer 410.

According to the described display device, moisture from an atmosphere is prevented from permeating to the display device, thus the reliability of the display device is improved. Further, the elastic modulus can be controlled by alternately stacking the inorganic layer and the organic layer thereby allowing improvement of flexibility. Therefore, the passivation layer that is appropriate for the flexible display device can be provided.

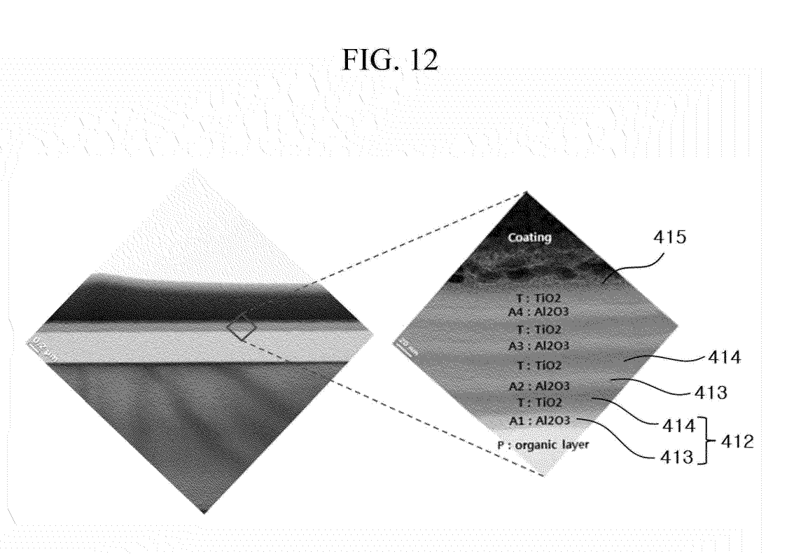

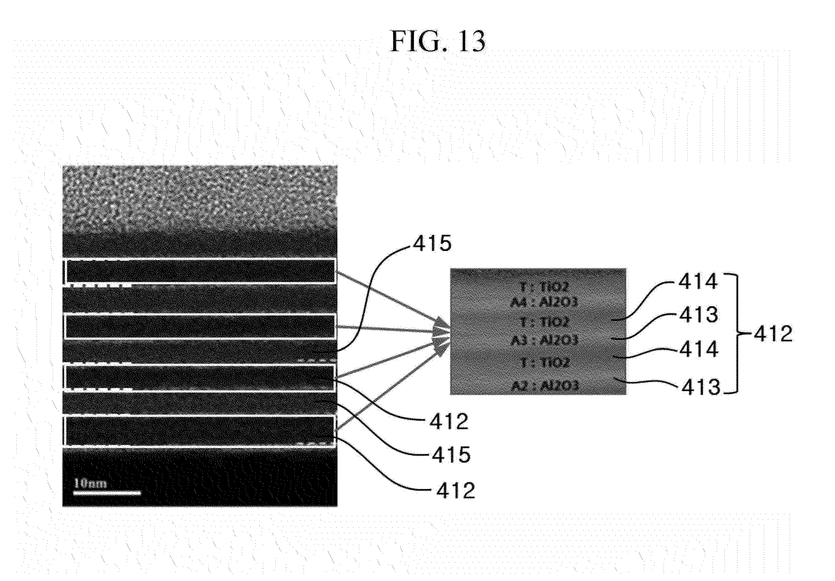

A passivation layer 410 according to another exemplary embodiment of the inventive concept will now be described with reference to FIG. 12 and FIG. 13. FIG. 12 and FIG. 13 show cross-sectional images of a passivation layer according to another exemplary embodiment of the inventive concept, and an exemplary embodiment of a passivation layer is modifiable in the described display device.

Referring to FIG. 12, the passivation layer 410 according to another exemplary embodiment of the inventive concept includes a plurality of inorganic layers 412 and an organic layer 415 provided on the inorganic layers 412. That is, the first inorganic layer 413 and the second inorganic layer 414 can be alternately stacked a plurality of times, and the organic layer 415 can be provided on the outermost second inorganic layer 414.

Further, the passivation layer 410 shown in FIG. 12 can be repeatedly provided. That is, as shown in FIG. 13, the first inorganic layer 413 and the second inorganic layer 414 can be alternately stacked a plurality of times, the organic layer 415 can be laminated on the first inorganic layer 413 and the second inorganic layer 414 repeatedly formed, and the above described structure may be repeated a plurality of times.

The stacked structure that is shown in FIG. 12 and FIG. 13 also has a somewhat unclear boundary in a like manner of the exemplary embodiment of the inventive concept.

According to the above-described stacked structure, the use of the stacked structure of the inorganic layer and the organic layer prevents permeation of moisture and increases a permeation path of permeating moisture to improve reliability of the display device.

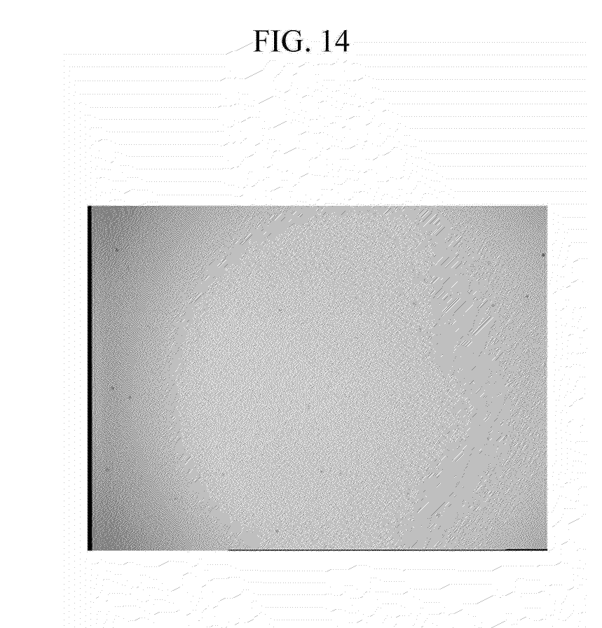

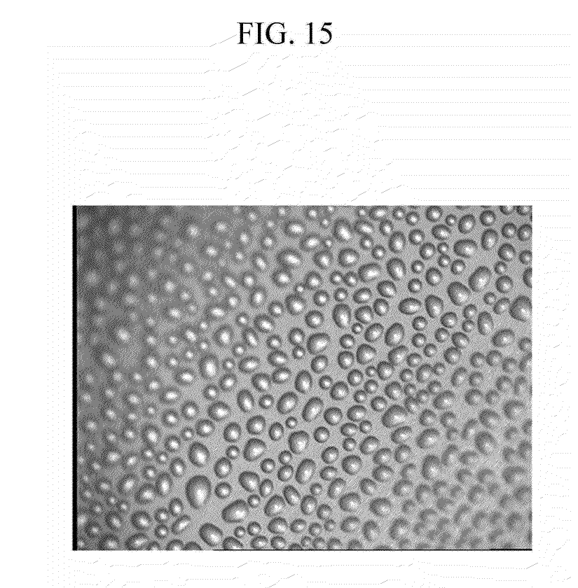

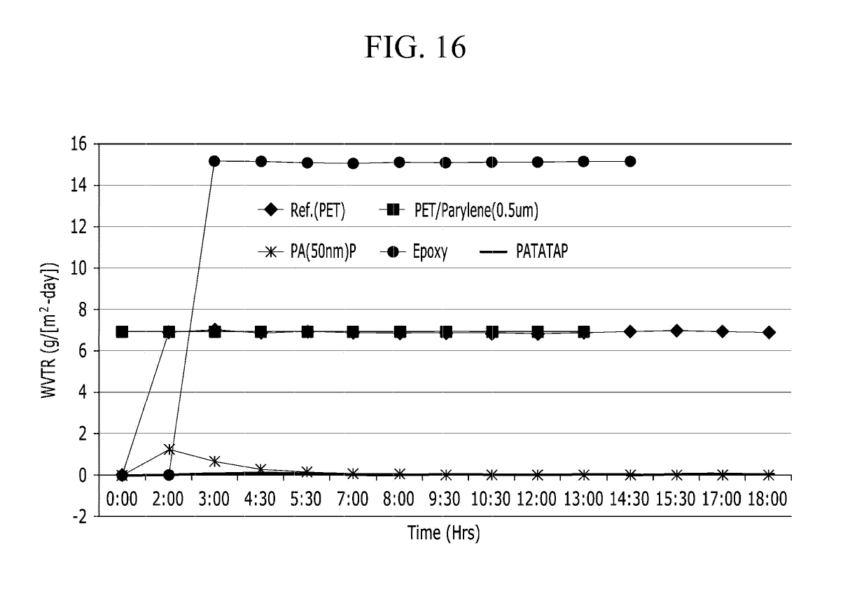

A moisture permeation level of the display device according to an exemplary embodiment of the inventive concept will now be described with reference to FIG. 14 to FIG. 16. FIG. 14 shows an image of the device after dipping the device into water to evaluate the passivation layer according to an exemplary embodiment of the inventive concept, and FIG. 15 shows an image of the device after dipping the device into water to evaluate the passivation layer for a comparative example. FIG. 16 shows a graph for moisture permeability for a passivation layer according to an exemplary embodiment of the inventive concept and a comparative example.

Referring to FIG. 14, the passivation layer according to the exemplary embodiment of the inventive concept shows a surface that does not release moisture even after a long-term dipping. That is, it shows that it is difficult for moisture to permeate into the passivation layer so no moisture is discharged from the passivation layer after a long term dipping.

On the contrary, FIG. 15 shows an image of the comparative device after dipping the device into water to evaluate the passivation layer having an organic layer as a passivation layer. The comparative example shown in FIG. 15 shows that moisture is released on the surface of the passivation layer with the lapse of time. This signifies that the moisture having permeated into the organic layer is discharged to the surface as time passes. That is, it shows that a large amount of moisture has permeated into the organic layer.

Therefore, according to FIG. 14 and FIG. 15, the passivation layer including a plurality of inorganic layers according to an exemplary embodiment of the inventive concept shows better performance in preventing permeation of moisture than the passivation layer having only an organic layer.

FIG. 16 shows a graph of an amount of permeated moisture according to a material of the passivation layer.

Regarding usage of a passivation layer that is a PET film (Ref), the amount of moisture in the layer is increased in a short time and the amount of moisture in the layer is saturated to have about 7 g/m²day. The passivation layer for coating parylene on the PET film also shows substantially the same amount of permeated moisture.

An epoxy film shows about 15 g/m²day in a short time, which shows that a substantial amount of moisture has permeated into the film.

However, the passivation layer (PAP) including the inorganic layer of aluminum oxide shows the amount of permeated moisture that is less than 2 g/m²day, and it shows the amount of permeated moisture that is close to 0 as the time passes. Further, the passivation layer (PATATAP) including the inorganic layer on which aluminum oxide and titanium oxide are alternately stacked shows the amount of permeated moisture that is nearly close to 0 without regard to time.

It is determined that the passivation layer including the inorganic layer according to the embodiment of the inventive concept has an excellent water barrier capability, thereby providing reliability of the display device.

While this inventive concept has been described in connection with what is presently considered to be practical exemplary embodiments, it is to be understood that the inventive concept is not limited to the disclosed embodiments, but, on the contrary, is intended to cover various modifications and equivalent arrangements included within the spirit and scope of the appended claims.

What is claimed is:

1. A display device comprising:
an insulation substrate including a plurality of pixel areas;
a thin film transistor provided on the insulation substrate;
a pixel electrode connected to the thin film transistor;
a liquid crystal layer filling a microcavity;
a common electrode provided on the liquid crystal layer and separated from the pixel electrode by the microcavity;
a roof layer provided on the common electrode;
an injection hole formed on the common electrode and the roof layer to expose part of the microcavity;
an overcoat formed on the roof layer to cover the injection hole and seal the microcavity; and
a passivation layer provided on the overcoat, wherein the passivation layer includes an inorganic layer.

2. The display device of claim 1, wherein the passivation layer further includes an organic layer.

3. The display device of claim 2, wherein the inorganic layer includes a first inorganic layer and a second inorganic layer which are alternately disposed.

4. The display device of claim 4, wherein the first inorganic layer and the second inorganic layer are about 1 Å thick.

5. The display device of claim 3, wherein the first inorganic layer includes an aluminum oxide and the second inorganic layer includes a titanium oxide.

6. The display device of claim 2, wherein the organic layer includes at least one of polyamide, nylon 6, nylon 66, polyethylene, polypropylene, polyurea, polythiourea, polyurethane, polyester, and polyazomethine.

7. The display device of claim 1, wherein
the inorganic layer includes at least one of aluminum oxide, titanium oxide, and tin oxide.

8. The display device of claim 7, wherein the inorganic layer includes a first inorganic layer and a second inorganic layer which are alternately disposed.

9. The display device of claim 8, further comprising an organic layer disposed on the inorganic layer.

10. The display device of claim 9, wherein the inorganic layer includes a plurality of inorganic layers and the organic layer includes a plurality of organic layers, and
wherein the plurality of inorganic layer and the plurality of organic layer are alternately disposed.

11. The display device of claim 8, wherein the inorganic layer is repeatedly disposed.

12. The display device of claim 11, further comprising an organic layer disposed on the inorganic layer.

13. A method for manufacturing a display device, comprising:
forming a thin film transistor on a substrate;
forming a first insulating layer on the thin film transistor;
forming a pixel electrode connected to the thin film transistor on the first insulating layer;
forming a sacrificial layer on the pixel electrode;
forming a common electrode on the sacrificial layer;
forming a second insulating layer on the common electrode;
coating an organic material on the second insulating layer and patterning the same to form a roof layer;
exposing the sacrificial layer;
forming a microcavity between the pixel electrode and the common electrode by removing the sacrificial layer through an exposed region;
forming a liquid crystal layer by injecting a liquid crystal material into the microcavity;
sealing the microcavity by forming an overcoat on the roof layer; and
forming a passivation layer on the overcoat,
wherein the passivation layer includes an inorganic layer.

14. The method of claim 13, wherein the passivation layer further includes an organic layer, and
wherein the inorganic layer is formed by using an atomic layer deposition (ALD) method and the organic layer is formed by using a molecular layer deposition (MLD) method.

15. The method of claim 14, wherein the passivation layer is formed by alternately laminating the organic layer and the inorganic layer, and
wherein the alternately laminating the organic layer and the inorganic layer are performed repeatedly.

16. The method of claim 14, wherein
the organic layer includes at least one of polyamide, nylon 6, nylon 66, polyethylene, polypropylene, polyurea, polythiourea, polyurethane, polyester, and polyazomethine.

17. The method of claim 14, wherein the inorganic layer includes a first inorganic layer and a second inorganic layer which are alternately disposed, and
wherein the first inorganic layer includes an aluminum oxide and the second inorganic layer includes a titanium oxide.

18. The method of claim 14, wherein the inorganic layer is about 1 Å thick.

19. The method of claim 13, wherein the inorganic layer includes at least one of aluminum oxide, titanium oxide, and tin oxide.

20. The method of claim 13, wherein the inorganic layer is formed by alternately laminating different kinds of first inorganic layers and second inorganic layers.
